(19) United States
(12) Patent Application Publication
(10) Pub. No.: US 2025/0070090 A1
(43) Pub. Date: Feb. 27, 2025

(54) STACKED MEMORY DEVICES WITH MIXED-BANDWIDTH MEMORY DIES

(71) Applicant: Micron Technology, Inc., Boise, ID (US)

(72) Inventors: Dong Uk Lee, Boise, ID (US); Raghukiran Sreeramaneni, Frisco, TX (US); Yen Chun Lee, Boise, ID (US)

(21) Appl. No.: 18/789,675

(22) Filed: Jul. 31, 2024

Related U.S. Application Data
(60) Provisional application No. 63/534,091, filed on Aug. 22, 2023.

(51) Int. Cl. H01L 25/065; H10B 80/00

(52) U.S. Cl. CPC H01L 25/0657; H10B 80/00; H01L 2225/06541

(57) ABSTRACT

A memory device is provided. The memory device includes a plurality of memory dies positioned in a stack, the stack including a first set of memory dies and a second set of memory dies. Each die in the first set includes a first plurality of channels in a first configuration that includes channels configured to operate in a first bandwidth mode and channels configured to operate in a second bandwidth mode. Each die in the second set includes a second plurality of channels in a second configuration that includes channels configured to operate in the second bandwidth mode.

### CROSS-REFERENCE TO RELATED APPLICATION(S)

The present application claims priority to U.S. Provisional Patent Application No. 63/534,091, filed Aug. 22, 2023, the disclosure of which is incorporated herein by reference in its entirety.

### TECHNICAL FIELD

The present disclosure generally relates to stacked semiconductor memory devices, and more particularly relates to stacked memory devices with mixed-bandwidth memory dies.

### BACKGROUND

Memory devices are widely used to store information related to various electronic devices such as computers, wireless communication devices, cameras, digital displays, and the like. Memory devices may be volatile or non-volatile and can be of various types, such as magnetic hard disks, random access memory (RAM), read-only memory (ROM), dynamic RAM (DRAM), synchronous dynamic RAM (SDRAM), and others. Information is stored in various types of RAM by charging a memory cell to have different states. Improving RAM memory devices, generally, can include increasing memory cell density, increasing read/write speeds or otherwise reducing operational latency, increasing reliability, increasing data retention, reducing power consumption, or reducing manufacturing costs, among other metrics.

### BRIEF DESCRIPTION OF THE DRAWINGS

FIG. 1 illustrates a simplified schematic cross-sectional view of an example memory device.

FIG. 2 illustrates a simplified schematic cross-sectional view of a memory device in accordance with embodiments of the present technology.

FIG. 3 illustrates a simplified exploded plan view of memory die belonging to a memory device in accordance with embodiments of the present technology.

FIG. 4 illustrates a mode selection circuit for choosing a bandwidth mode of a channel on a memory die in accordance with embodiments of the present technology.

FIG. 5 illustrates a simplified schematic plan view of a memory die with voltage regulators in accordance with embodiments of the present technology.

FIG. 6 illustrates a flow chart illustrating a method for choosing a bandwidth for a channel on a memory die in accordance with embodiments of the present technology.

FIG. 7 illustrates a block diagram of a system that includes a semiconductor memory device configured in accordance with embodiments of the present technology.

### DETAILED DESCRIPTION

High data reliability, high speed of memory access, lower power consumption and reduced chip size are features that are demanded from semiconductor memory. In recent years, three-dimensional (3D) memory devices have been introduced. Some 3D memory devices are formed by stacking dice vertically and interconnecting the dice using through-silicon (or through-substrate) vias (TSVs). Benefits of the 3D memory devices include shorter interconnects which reduce circuit delays and power consumption, a large number of vertical vias between layers which allow wide bandwidth buses between functional blocks in different layers, and a considerably smaller footprint. Thus, the 3D memory devices contribute to higher memory access speed, lower power consumption, and chip size reduction. Example 3D memory devices include Hybrid Memory Cube (HMC) and High Bandwidth Memory (HBM). For example, HBM is a type of memory including a high-performance random access memory (DRAM) interface and vertically stacked DRAM.

An HBM device may be comprised of a vertical stack of different numbers of memories dies (e.g., DRAM dies), such as a stack of eight memory dies stacked vertically onto another (referred to as eight-high, 8-Hi, or an 8H stack), twelve memory dies stacked vertically onto another (referred to as twelve-high, 12-Hi, or a 12H stack), etc. Additionally, the HBM device may include multiple independent channels used to communicate with a host coupled to the HBM device (e.g., a CPU, GPU, memory controller, etc.). Each channel may include its own clock, command/address, and data interface, to enable operations that are independent of the channels. For example, an HBM device may include 32 channels (e.g., channels 0-31).

Further, the memory of an HBM device can be separated into one or more ranks. Each memory die of the HBM device may be associated with a rank, which may be identified by a chip select (CS) and/or stack ID (SID) signal. For example, in a 12H HBM device, in which the device has 32 channels and each of the 12 memory die has 4 channels on a die, 8 of the memory dies may be configured as a first rank, and the remaining 4 of the memory dies may be configured as a second rank. In said example, each channel of the HBM device would be capable of accessing memory in the HBM device associated with two different ranks (e.g., the first rank and the second rank). That is, different ranks of a channel share certain interfaces of the channel (e.g., command and I/O), but are associated with different physically accessed memory.

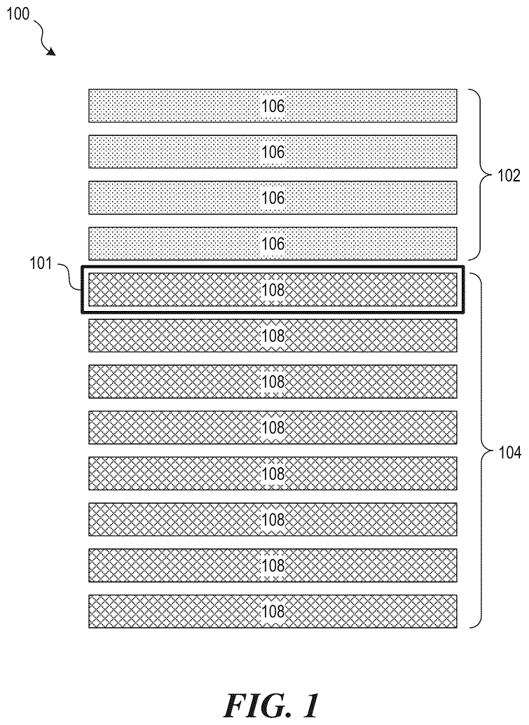

As explained above, each of the memory dies of the HBM device can include multiple channels, through which the memory of the memory die is accessed. For example, each memory die may include 2 channels, 4 channels, etc. Furthermore, different memory dies within the HBM device may operate to provide different bandwidths via their respective channels. Within an HBM device, different numbers of memory dies may be used to provide equivalent bandwidths, depending on the per-die bandwidths of the memory dies. For example, if an HBM device includes memory dies of two different bandwidths (e.g., full-bandwidth memory dies and half-bandwidth memory dies), the HBM device may include twice as many half-bandwidth memory dies as full-bandwidth memory dies, such that the half-bandwidth dies provide the same total bandwidth as the full-bandwidth memory dies. Furthermore, memory dies may be characterized based on the number of memory dies needed to achieve a target bandwidth. For example, an 8N die represents a memory die for which eight of that die is needed to achieve a target bandwidth, and a 4N die represents a memory die for which four of that die is needed to achieve the target bandwidth. One example of such an HBM device is shown in FIG. 1, which illustrates a simplified schematic cross-sectional view of a memory device 100. The memory device 100 illustrates a 12H device, and includes a 4-Hi stack 102 and an 8-Hi stack 104. As illustrated in FIG. 1, the 4-Hi stack 102 comprises four 4N memory die 106, and the 8-Hi stack 104 comprises eight 8N memory die 108. Each of the 4N memory die 106 may provide twice the bandwidth of each of the 8N memory die 108. That is, each 4N memory die 106 may include 4N channels. And each 8N memory die 108 may include 8N channels. It will be appreciated that since the 8-Hi stack 104 includes 8N channels of half the bandwidth of the 4N channels, but includes twice the number of memory dies as in the 4-Hi stack 102, the 8-Hi stack and 4-Hi stack provide equivalent total bandwidth. Further, each of the channels (not shown) of the memory device 100 may be configured to provide the same bandwidth. That is, in the illustrated example of FIG. 1, in which the memory device 100 includes a 4-Hi stack 102 of 4N channels and an 8-Hi stack 104 of 8N channels, every memory device channel may be configured to use a 4N channel and an 8N channel (e.g., identical combination of channels, and therefore identical bandwidths). That is, channels of the memory devices may be configured to use the same combination of channels (accounting for differences in bandwidths), so that each memory device channel provides the same bandwidth.

It will be appreciated that memory devices, such as HBM devices, formed from memory dies with different bandwidth capabilities can give rise to various shortcomings. For example, the memory dies with higher bandwidth capabilities may consume more power than the memory dies with lower bandwidth capabilities and/or place more demands on the power delivery system of the memory device. When the relative bandwidth capabilities of the dies are different enough (e.g., in the example above, some dies have twice the bandwidth of other dies), the power consumption demands of the memory device may be particularly concentrated in a fewer number of memory dies (e.g., the higher bandwidth memory dies). For example, in the memory device 100 illustrated in FIG. 1, power consumption may be concentrated on a hotspot memory die 101. In the example illustrated in FIG. 1, the hotspot memory 101 is one of the 8N memory die 108, for example the 8N memory die at the transition in the memory device 100 stack between 8N memory dies and 4N memory dies. However, in other cases, the hotspot memory die 101 can be another die in the memory device 100. For example, the hotspot memory die 101 can be a single 4N memory die 106, and can be positioned anywhere in the memory device 100 where power consumption is bottle-necked. It will be appreciated that when maximum power concentration is concentrated in one memory die (e.g., hotspot memory die 101) or a fewer number of memory dies of a memory device, the memory device may suffer from poor heat concentration and strain on the power delivery to the memory device overall. For example, the power delivery network responsible for delivering power to the memory device could collapse.

Accordingly, to address these and other shortcoming, various embodiments of the present disclosure provide memory devices with mixed-bandwidth memory dies. As described herein, a memory die of the present disclosure may be mixed-bandwidth in that channels of the memory die may be configured to operate in a first bandwidth mode (corresponding to a first bandwidth) or a second bandwidth mode (corresponding to a second bandwidth), with a mix of channels configured in the first and second bandwidth modes on the die. For example, some channels of a memory die may be configured to operate as a 4N channel, and other channels of the memory die may be configured to operate as an 8N channel. It will be appreciated that with mixed-bandwidth memory dies, where memory dies can be configured to have a mix of higher-bandwidth and lower-bandwidth channels, the higher-bandwidth channels may be spread over a greater number of memory dies (e.g., not concentrated in a fewer number of memory dies, as illustrated by the memory device 100 in FIG. 1). Accordingly, since the higher-bandwidth channels are spread more throughout the memory device (e.g., over a greater number of memory dies), the power consumption demands of the higher-bandwidth channels are more dispersed. As a result, requirements of the power delivery network and addressing heat are improved compared to conventional memory devices.

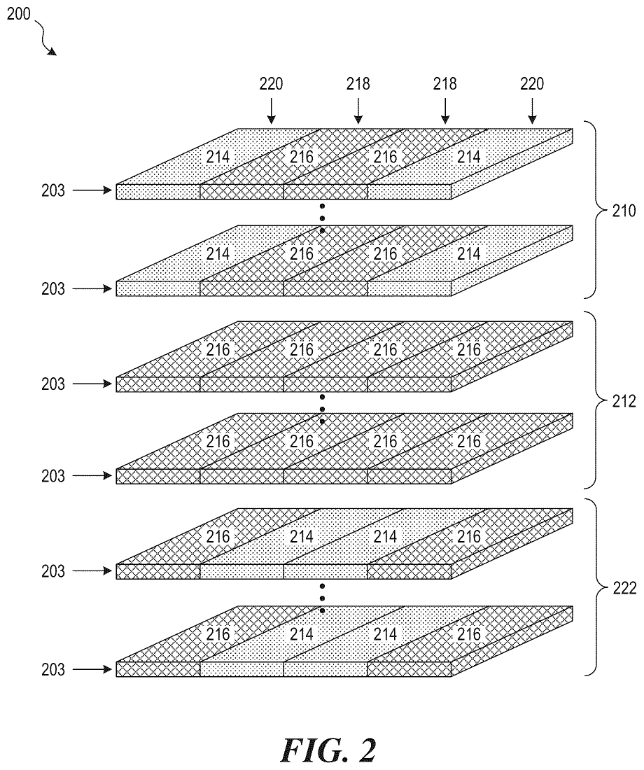

FIG. 2 illustrates a simplified schematic cross-sectional view of a memory device 200 in accordance with embodiments of the present technology. As can be seen with reference to FIG. 2, the memory device 200 can include a plurality of memory dies 203 positioned in a stack. As described herein, one or more of the memory dies 203 can be configured to operate as a mixed-bandwidth memory die. The memory device 200 can include a first set 210 of memory dies 203, a second set 212 of memory dies, and a third set 222 of memory dies. As illustrated in FIG. 2, the first set 210, second set 212, and third set 222 can be arranged in a vertical stack. As described herein, the memory dies 203 of the memory device 200 can include multiple channels (e.g., two channels per memory die, or four channels per memory die as illustrated in FIG. 2), and the channels can be configured differently depending on whether the die is part of the first set 210, second set 212, or third set 222.

In the embodiment of the present technology illustrated in FIG. 2, each memory die 203 in the first set 210 can be configured according to a first configuration, in which some channels are configured to operate in a first bandwidth mode 214, and other channels are configured to operate in a second bandwidth mode 216. The memory dies 203 in the second set 212 can be configured according to a second configuration, in which all channels are configured to operate in the second bandwidth mode 216. And the memory dies 203 in the third set 222 can be configured according to a third configuration, in which some channels are configured to operate in a first bandwidth mode 214, and other channels are configured to operate in a second bandwidth mode 216.

As illustrated in FIG. 2, the memory dies 203 of the memory device 200 can include inner channels 218 disposed on an inner portion of the memory die, and outer channels 220 disposed on an outer portion of the memory die. In embodiments of the present technology, the inner channels 218 of a memory die 203 are configured to operate in the same bandwidth mode, and the outer channels 220 of the memory die are configured to operate in the same bandwidth mode. In some embodiments of the present technology, the inner channels 218 may be configured to operate in a bandwidth mode different than the bandwidth mode of the outer channels 220. For example, as illustrated in FIG. 2, the memory dies 203 of the first set 210 of the memory device 200 can be configured such that the inner channels 218 operate according to a second bandwidth mode 216 and the outer channels 220 operate according to a first bandwidth mode 214. As a further example, the memory dies 203 of the second set 212 of the memory device 200 can be configured such that both the inner channels 218 and outer channels 220 operate according to the second bandwidth mode 216. And as a still further example, the memory dies 203 of the third set 212 of the memory device 200 can be configured such that the inner channels 218 are configured to operate according to a first bandwidth mode 214 and the outer channels 220 configured to operate according to a second bandwidth mode 216. Further, each of the memory channels of the memory device 200 are configured to have the same number of channels of the first bandwidth mode 214 and channels of the second bandwidth mode 216. For example, as illustrated in FIG. 1 each outer channel 220 and inner channel 218 includes two channels of the first bandwidth mode 214 and four channels of the second bandwidth mode 216. As a result, each of the outer channels 220 and inner channels 218 can provide the same total bandwidth. Further, the outer channels 220 and inner channels 218 utilize channels from dies at different locations within the vertical stack of memory device 200. For example, the channels of the first bandwidth mode 214 associated with the outer channels 220 can be located on the memory dies 203 of the first set 210, while channels of the first bandwidth mode 214 associated with the inner channels 218 can be located on the memory dies 203 of the third set 222. It will be appreciated that the present technology encompasses embodiments with additional (e.g., more than three) or fewer (e.g., fewer than three) sets of memory devices. It will also be appreciated that the present technology encompasses embodiments in which memory devices in the sets may be configured differently than what is illustrated in FIG. 2.

As discussed above, the plurality of memory dies 203 can be positioned in a vertical stack to form the memory device 200, as illustrated in FIG. 2. For example, the first set 210 of memory dies 203 can be disposed on a top of the stack, the third set 222 of memory dies 203 can be disposed on a bottom of the stack, and the second set 212 of memory dies 203 can be disposed between the first set 210 and the third set 222. In some embodiments, the plurality of memory dies 203 can be apportioned equally between the first set 210, second set 212, and third set 222. For example, in a 12H memory device 200, each of the first set 210, second set 212, and third set 222 may include 4 memory dies 203.

The first bandwidth mode 214 can correspond to a first bandwidth, while the second bandwidth mode 216 can correspond to a second bandwidth. The first bandwidth can be greater than the second bandwidth. For example, the first bandwidth can be twice the bandwidth of the second bandwidth. In some embodiments each memory dies 203 includes four channels, where at most two channels of a memory die 203 can be configured to operate in the first bandwidth mode 214, and at most four channels of the memory die 203 can be configured to operate in the second bandwidth mode 216. In some embodiments, the memory device 200 can include twice as many channels configured to operate in the second bandwidth mode 216 as it does channels configured to operate in the first bandwidth mode 214.

In some embodiments, the memory device 200 can be an HBM device. For example, in the example of FIG. 2, the memory device 200 may illustrate a 12H HBM device (e.g., formed from a twelve-high stack of memory die), in which the first set 210, second set 212, and third set 222 each include four memory dies 203 (for a total of twelve memory die). Furthermore, channels configured according to the first bandwidth mode 214 may correspond to 4N channels, and channels configured according to the second bandwidth mode 216 may correspond to 8N channels. Additionally, memory dies 203 may include twice as many 8N channels as 4N channels. As described herein, each 4N channel may provide twice the bandwidth of an 8N channel, such that all of the 4N channels of the memory device 200 provide the same total bandwidth as all of the 8N channels of the memory device. It will be appreciated however that, in comparison to conventional memory devices, the 4N memory channels are more distributed among the memory dies 203 of the memory device 200 (for example, in the embodiment illustrated in FIG. 2, among the memory dies of the first set 210 and third set 222).

In some embodiments of the present technology, the channels of a mixed-bandwidth memory die can be provided with different voltages, depending on the configuration of that channel (e.g., in what bandwidth mode the channel is operating). For example, each channel on the mixed-bandwidth memory die can be coupled with one or more associated voltage regulators that control a variable amount of voltage supplied to that channel. As described herein, the control circuitry of the memory device can determine the bandwidth mode of the different channels of the mixed-bandwidth memory die, and configure the associated voltage regulators accordingly.

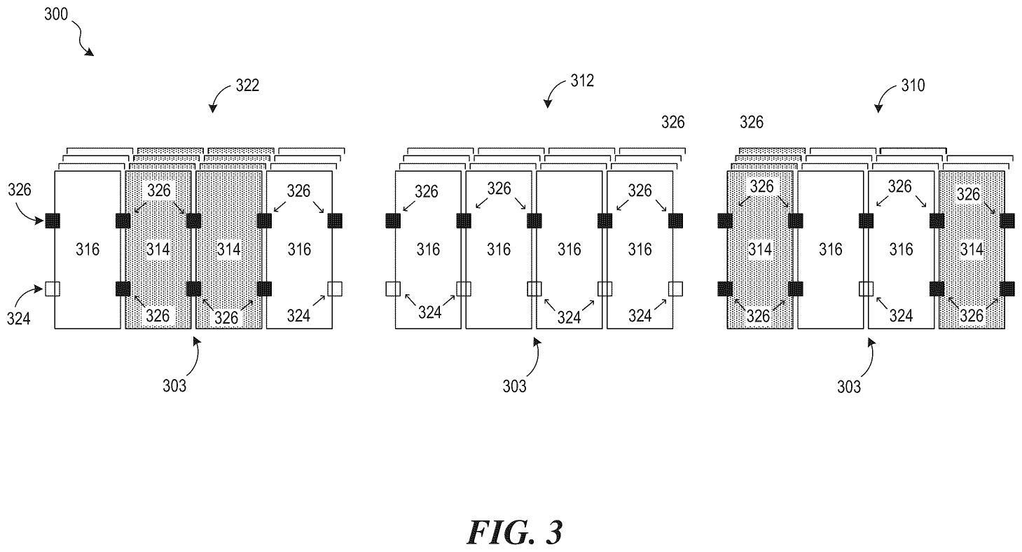

FIG. 3 illustrates a simplified exploded plan view of memory dies belonging to a memory device 300 in accordance with embodiments of the present technology. The memory device 300 can be an HBM device. The memory device 300 can include a first set 310, second set 312, and third set 322 of mixed-bandwidth memory dies 303. The first set 310, second set 312, and third set 322 of mixed-bandwidth memory dies 303 can be arranged in a vertical stack in the memory device 300 (e.g., one set on top of another), although illustrated in FIG. 3 an exploded plan view (e.g., one set next to another). The mixed-bandwidth memory dies 303 may include multiple channels, where the channels disposed on the inner portion of the die may be configured to operate in a first bandwidth mode 314 or a second bandwidth mode 316, and the channels disposed on the outer portion of the die may be configured to operate in the first bandwidth mode 314 or the second bandwidth mode 316. Furthermore, each of the channels may be coupled to a plurality of associated voltage regulators, which may be configured to be enabled and supply voltage to the channel (enabled voltage regulators 324) or configured to be disabled and not supply voltage to the channel (disabled voltage regulators 326). The memory device 300 can control the amount of total voltage supplied to each channel based on the number of voltage regulators coupled to that channel that are enabled. That is, the voltage regulators can be configured to supply a first voltage to the channels configured to operate in the first bandwidth mode 314, and a second voltage to the channels configured to operate in the second bandwidth mode 316, based on the combination of voltage regulators enabled for each channel. The second voltage can be greater than the first voltage (e.g., when the first bandwidth mode is associated with a bandwidth greater than a bandwidth associated with the second bandwidth mode). In some embodiments, all of the voltage regulators associated with a channel may need to be enabled in order for the channel to operate in the first bandwidth mode 314. In some embodiments, some of the voltage regulators associated with a channel may need to be enabled, but other associated voltage regulators may need to be disabled, in order for the channel to operate in the second bandwidth mode 316. For example, as illustrated in FIG. 3, all of the voltage regulators coupled to the channels operating in the first bandwidth mode 314 are enabled voltage regulators 324, whereas the voltage regulators coupled to the channels operating in the second bandwidth mode 316 are a mix of enabled voltage regulators 324 and disabled voltage regulators 326. The memory device 300 can further include voltage generator control that is connected to and configured to control the plurality of voltage regulators for each memory die 303, based for example on the bandwidth mode of corresponding channels.

The memory device 300 can further include a mode selection circuit, which may be coupled to and configured to control (e.g., enable or disable) the voltage regulators for each mixed-bandwidth memory die 303 depending on the mode of die's channels. Each mixed-bandwidth memory die 303 can include one or more mode selection circuits, configured to select the first bandwidth mode 314 or the second bandwidth mode 316 for a channel, based on a position of the mixed-bandwidth memory die 303 in the stack of the memory device 300 and a position of the channel on the die 303. For example, the mode selection circuit may select a different mode for channels on the same mixed-bandwidth memory die 303 depending on whether the channels are disposed on the inner portion or outer portion of the memory die. In some embodiments the mode selection circuit additionally makes the mode selection based on a mode setting, which indicates whether mixed-bandwidths within a die are enabled for the memory device 300 (e.g., a channel-mix setting for the memory device 300). The control circuit of a mixed-bandwidth memory die 303 may receive an input, e.g. from an interface die of the memory device 300, that indicates the position of the mixed-bandwidth memory die in the stack. In some embodiments, the control circuit of a mixed-bandwidth memory die 303 receives an indication of the die's position from some other component of the die (e.g., a fuse, mode register, etc.) The interface die can be located at a bottom of the stack of mixed-bandwidth memory dies 303, and it can be connected to the plurality of mixed-bandwidth memory dies 303. In some embodiments, aspects of the one or more mode selection circuits may be part of the interface die or some other component of the memory device 300. In such embodiments, the interface die can be configured to control the mode selection circuit for each die and/or to perform the mode selection itself.

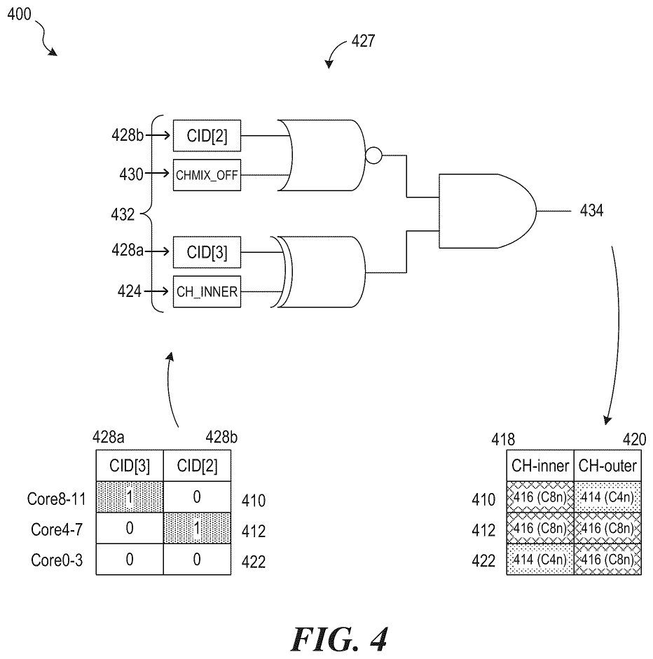

FIG. 4 illustrates a mode selection circuit 400 for choosing a bandwidth mode of a channel on a memory die, in accordance with embodiments of the present technology. As described herein, the mode selection circuit 400 may be part of a memory die, interface die, or other components of a memory device. Additionally, there may be multiple mode selection circuits 400, each of which selects a bandwidth mode for a particular memory die and/or channel disposed on the memory die. The mode selection circuit 400 includes logic 427 that determines a bandwidth mode from a set of bandwidth modes for each channel. For example, the logic 427 can determine whether a corresponding channel should be configured as a 4N channel or an 8N channel. The logic 427 may generate a mode selection output 434 (e.g., indicating whether the channel is configured as a 4N channel or 8N channel) based on one or more inputs 432. For example, if the mode selection output 434 is set to 1, or a logically true value, it may indicate that the channel is configured to a 4N mode 414. If the mode selection output 434 is set to 0, or a logical false value, it may indicate that the channel is configured to an 8N mode 416. The inputs 432 can include a channel position input 424 (e.g., characterizing the position of the channel being configured by the mode selection output 434 on the memory die), die position input 428 (e.g., characterizing the position of the memory die within the vertical stack of an HBM device), and a channel-mix setting input 430 of the memory device. In some embodiments, the die position input 428 is comprised of multiple bits (e.g., the most-significant bits) that identify the memory die. For example, each memory die may be associated with a multi-bit core ID (“CID”), and as illustrated in FIG. 3, the die position input 428 may be comprised of CID [2] 428a and CID [3] 428b. In some embodiments, the die position input indicates the set of memory devices in which the memory device is positioned. For example, in embodiments in which the HBM device has twelve memory dies (e.g., it is a 12H HBM device) split into three sets of four memory dies each, CID [2] 428a and CID [3] 424b indicate which of the three sets the memory die belongs to. In some embodiments, the channel position input 424 indicates whether the channel being configured by the mode selection output 434 is disposed on the inner portion of a die or the outer portion of the die. As described herein, the mode selection output 434 can be used as an input by a voltage generator control of the memory device. For example, the voltage generator control can determine an amount of current to be supplied to voltage regulators for the channel. The amount of current can correspond to the bandwidth mode selected by the mode selection circuit. In certain implementations of the mode selection circuit 400, the output 434 can designate a subset of 8N channels that numbers twice as many channels as a subset of 4N channels within the memory device.

Examples of the operation of the mode control circuit 400 are now described. For example, for a channel having a CH_INNER value of 0 (e.g., an outer channel), on a die with a CID [2] of 0 and a CID [3] of 1 (e.g., one of cores 8-11, belonging to a first set 410, as illustrated in the table of FIG. 4), in a memory device with a CHMIX_OFF value of 0, the output 434 will be 1, indicating that the mode selection circuit will configure that channel to be a 4N channel, setting the bandwidth mode for that channel to a full-bandwidth mode, or a high bandwidth mode. As another example, a channel having a CH_INNER value of 1 (e.g., an inner channel), on a die with a CID [2] of 1 and a CID [3] of 0 (e.g., one of cores 4-7, belonging to a second set 412, as illustrated in the table of FIG. 4), in a memory device with a CHMIX_OFF value of 0, the output 434 of the mode selection logic 427 will be 0. This indicates the channel is a designated 8N channel based on the inputs 432, setting the bandwidth mode for that channel to a half-bandwidth mode, or a low bandwidth mode.

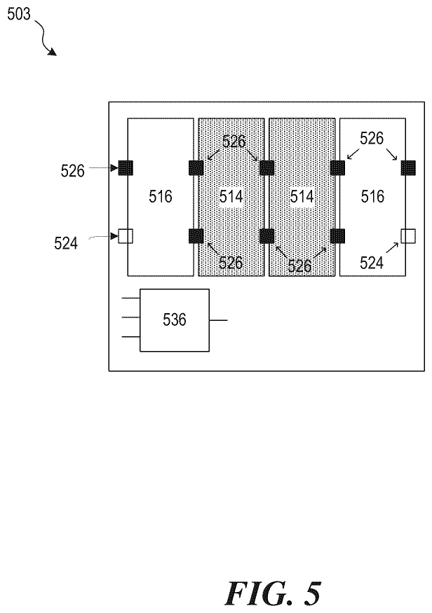

Turning to FIG. 5, a memory die 503 in accordance with embodiments of the present technology is illustrated. The memory die 503 includes a set of full-bandwidth channels 514 associated with a first set of voltage regulators set to an on position 524. The set of full-bandwidth channels 514 have a position on an inner portion 518 of the memory die. Alternatively, the set of full-bandwidth channels 514 can have a position on an outer portion 520 of the memory die. Also included in the memory die 503 is a set of half-bandwidth channels 516 associated with a second set of voltage regulators set to an off position 526. Alternatively, the second set of voltage regulators can be set to a combination of the off position 526 and on position 524, as illustrated. The set of half-bandwidth channels 516 can be disposed on a portion of the die not occupied by the full-bandwidth channels, as depicted in FIG. 5. Alternatively, the set of half-bandwidth channels 516 and full-bandwidth channels 514 can be mixed across the inner and outer portions, 518 and 520, of the memory die 503. The memory die 503 can also include a mode selection circuit 536. The mode selection circuit 536 can be configured to enable or disable the first and second sets of voltage regulators by changing their position from off to on or from on to off. The mode selection circuit 536 can take as input the position of the channel that is associated with the set of voltage regulators, an ID of the memory die 503, and a channel-mix setting of the memory die 503. The full-bandwidth channels 514 can have twice as much bandwidth as the half-bandwidth channels 516. Additionally, every channel is configured to transfer data to and from the memory die 503.

In accordance with one aspect of the present disclosure, the semiconductor devices illustrated in FIGS. 2-5 could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single memory device, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the memory devices illustrated and described above could be logic dies (e.g., interface dies, controller dies, processor dies, etc.), or a mix of logic and memory dies (e.g., a memory controller die and a memory die controlled thereby).

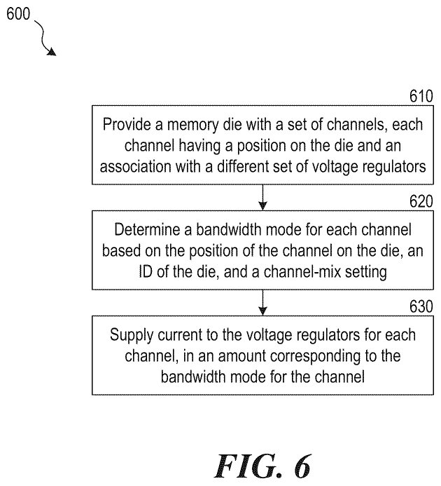

FIG. 6 is a flow chart illustrating a method 600 of choosing a bandwidth for a channel on a memory die. The method includes providing a memory device. The memory device can include a vertical stack of memory die, a voltage generator control, and a channel-mix setting. Each die in the stack can include a mode selection circuit, a set of channels, and a core ID (CID). Each channel can further include a set of voltage regulators and a position on the die (step 610). The method further includes determining a bandwidth mode from a set of bandwidth modes for each channel. The determination can be based on the position of the channel on the die, the CID of the die, and the channel-mix setting of the memory device in each die's mode selection circuit (step 620). The method additionally includes the voltage generator control supplying current to the voltage regulators for each channel. The amount of current supplied can correspond to the bandwidth mode for that channel (step 630).

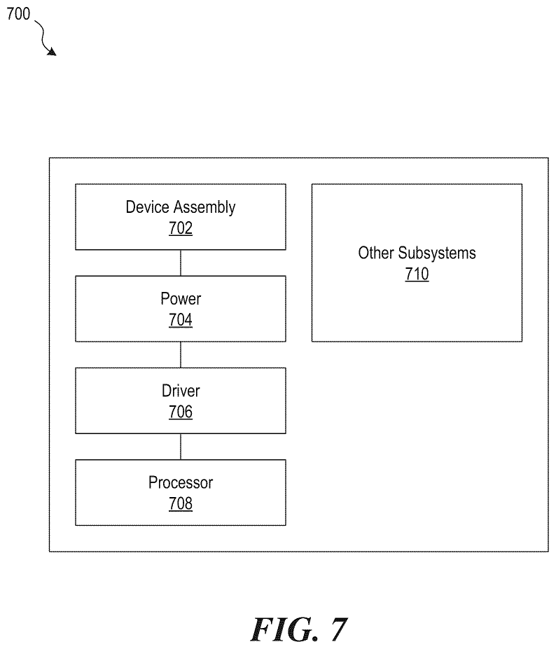

Any one of the semiconductor devices and semiconductor device assemblies described above with reference to FIGS. 2-5 can be incorporated into any of a myriad of larger and/or more complex systems, a representative example of which is system 700 shown schematically in FIG. 7. The system 700 can include a semiconductor device assembly (e.g., or a discrete semiconductor device) 702, a power source 704, a driver 706, a processor 708, and/or other subsystems or components 710. The semiconductor device assembly 702 can include features generally similar to those of the semiconductor devices described above with reference to FIGS. 2-5. The resulting system 700 can perform any of a wide variety of functions, such as memory storage, data processing, and/or other suitable functions. Accordingly, representative systems 700 can include, without limitation, hand-held devices (e.g., mobile phones, tablets, digital readers, and digital audio players), computers, vehicles, appliances and other products. Components of the system 700 may be housed in a single unit or distributed over multiple, interconnected units (e.g., through a communications network). The components of the system 700 can also include remote devices and any of a wide variety of computer readable media.

Although in foregoing examples embodiments have been illustrated and described as HBM devices, in other embodiments these can be flash memory packages, graphics memory packages, DDR, or GDDR with multiple memory dies. Likewise, the 8N and 4N channels can be replaced by channels of higher or lower bandwidths (e.g., channels with bandwidths for which greater or fewer number of memory dies of that bandwidth are needed to satisfy a bandwidth requirement). By extension, the distribution of high- and low-bandwidth channels throughout the memory device can be different from what has been illustrated and described, e.g., the first set 210 illustrated in FIG. 2 could have a distribution of 1-4N channel and 3-8N channels on every memory die, while the second set 212 could have a distribution of 2-4N channels and 2-8N channels, mutatis mutandis.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A memory device, comprising:
a plurality of memory dies positioned in a stack, the stack comprising:
a first set of memory dies, each die in the first set comprising:
a first plurality of channels configured according to a first configuration, wherein the first configuration comprises channels configured to operate in a first bandwidth mode, and channels configured to operate in a second bandwidth mode, and
a second set of memory dies, each die in the second set comprising:
a second plurality of channels configured according to a second configuration, wherein the second configuration comprises channels configured to operate in the second bandwidth mode.

2. The memory device of claim 1, wherein the first and second plurality of channels for each memory die comprises inner channels disposed on an inner portion of the memory die and outer channels disposed on an outer portion of the memory die.

3. The memory device of claim 2, wherein the outer channels in the first plurality are configured to operate in the first bandwidth mode.

4. The memory device of claim 2, wherein one or more of the inner channels and one or more of the outer channels in the first plurality are configured to operate in the first bandwidth mode.

5. The memory device of claim 3, comprising:
a third set of memory dies, each die in the third set comprising:
a third plurality of channels configured according to the first configuration, wherein the inner channels of the third plurality are configured to operate in the first bandwidth mode.

6. The memory device of claim 5, wherein the plurality of memory dies are positioned in a vertical stack, wherein the first set of memory dies are disposed on a top of the stack, wherein the third set of memory dies are disposed on a bottom of the stack, wherein the second set of memory dies are disposed between the first set and the third set, and wherein the plurality of dies are apportioned equally between the first set, second set, and third set.

7. The memory device of claim 1, wherein the memory device comprises twice as many channels configured to operate in the second bandwidth mode as channels configured to operate in the first bandwidth mode.

8. The memory device of claim 1, wherein the first bandwidth mode corresponds to a first bandwidth, the second bandwidth mode corresponds to a second bandwidth, and the first bandwidth is greater than the second bandwidth.

9. The memory device of claim 1, wherein each die comprises four channels, wherein at most two channels of a die are configured to operate in the first bandwidth mode, and wherein at most four channels of the die are configured to operate in the second bandwidth mode.

10. The memory device of claim 6, wherein the memory device is an HBM cube, wherein the plurality of memory dies comprises a 12-Hi stack of core DRAM die, and wherein the first bandwidth mode comprises a 4-Hi full bandwidth mode and the second bandwidth mode comprises an 8-Hi full bandwidth mode.

11. The memory device of claim 1, wherein the device comprises an interface die connected to the plurality of memory die, wherein each die in the plurality comprises a mode selection circuit configured to select the first bandwidth mode or the second bandwidth mode based on a position of the die in the stack, a position of the channel on the die, and a channel-mix setting for the memory device, and wherein the interface die is configured to control the mode selection circuit for each die.

12. The memory device of claim 11, wherein each channel is associated with a plurality of voltage regulators configured to supply a first voltage for the first bandwidth mode and a second voltage for the second bandwidth mode, wherein the second voltage is greater than the first voltage, wherein the memory device comprises a voltage generator control connected to and configured to control the plurality of voltage regulators for each memory die, and wherein the voltage generator control takes as input a signal from the mode selection circuit.

13. A method of choosing a bandwidth for a channel on a memory die in a vertical stack of memory dies in a semiconductor memory device, the method comprising:
providing a memory device comprising a vertical stack of memory dies, a voltage generator control, and a channel-mix setting, each die in the stack comprising a mode selection circuit, a set of channels, and a core ID (CID), and each channel comprising a set of voltage regulators and a position on the die;
in each die's mode selection circuit, determining a bandwidth mode from a set of bandwidth modes for each channel based on the position of the channel on the die, the CID of the die, and the channel-mix setting of the memory device; and
in the voltage generator control, supplying an amount of current to the voltage regulators for each channel, the amount of current corresponding to the bandwidth mode of the channel.

14. The method of claim 13, wherein the CID depends on a position of the die in the stack.

15. The method of claim 13, wherein the set of bandwidth modes includes a half-bandwidth mode and a full-bandwidth mode, and wherein the full-bandwidth mode has twice the bandwidth as the half-bandwidth mode.

16. The method of claim 15, wherein each voltage regulator has an on position and an off position.

17. The method of claim 16, wherein supplying an amount of current to the voltage regulators further comprises:
determining a subset of channels in full-bandwidth mode based on the determination of the mode selection circuit; and
setting voltage regulators to the on position for the subset of channels in full-bandwidth mode.

18. The method of claim 13, wherein each channel is located on an inner portion of its die or an outer portion of its die.

19. The method of claim 17, wherein the subset of channels in full-bandwidth mode numbers half as many as a subset of channels in half-bandwidth mode.

20. A memory die, comprising:
a set of full-bandwidth channels associated with a first set of voltage regulators set to an on position, wherein the set of full-bandwidth channels have a position on an inner portion of the memory die or on an outer portion of the memory die;
a set of half-bandwidth channels associated with a second set of voltage regulators set to an off position, wherein the set of half-bandwidth channels are disposed on a portion of the die not occupied by the full-bandwidth channels; and
a mode selection circuit configured to enable or disable the first and second sets of voltage regulators by changing their position from off to on or from on to off, wherein the mode selection circuit takes as input the position of the channel that is associated with the set of voltage regulators, an ID of the memory die, and a channel-mix setting of the memory die,
wherein the full-bandwidth channels have twice as much bandwidth as the half-bandwidth channels, and
wherein every channel is configured to transfer data to and from the memory die.
